(19) United States
(12) Patent Application Publication
(10) Pub. No.: US 2025/0309144 A1
(43) Pub. Date: Oct. 2, 2025

(54) DISPLAY SUBSTRATE, TOUCH DISPLAY PANEL, AND TOUCH DISPLAY DEVICE

(71) Applicants: Wuhan Tianma MicroElectronics Co., Ltd. Shanghai Branch., Shanghai (CN); Wuhan Tianma Micro-Electronics Co., Ltd., Wuhan (CN)

(72) Inventors: Jingjing HUANG, Shanghai (CN); Qingxia Wang, Shanghai (CN)

(21) Appl. No.: 18/821,700

(22) Filed: Aug. 30, 2024

(30) Foreign Application Priority Data
Mar. 29, 2024 (CN) 202410384693.2

(51) Int. Cl. H01L 23/00; G06F 3/041; H01L 23/498

(52) U.S. Cl. CPC H01L 23/564; H01L 23/49838; G06F 3/0412; H01L 23/49866

(57) ABSTRACT

A display substrate, a touch display panel and a touch display device are provided. The display substrate includes: a base substrate including a bonding area; and first connecting pins and second connecting pins in the bonding area. Along a direction from the first connecting pins to the second connecting pins, an insulating structure is provided between the first connecting pins and the second connecting pins. One first connecting pin and one second connecting pin adjacent to each other are disposed in different conductive layers.

### CROSS-REFERENCE TO RELATED APPLICATION

This application claims the priority of Chinese Patent Application No. 202410384693.2, filed on Mar. 29, 2024, the content of which is incorporated herein by reference in its entirety.

### TECHNICAL FIELD

The present disclosure generally relates to the field of display technology and, more particularly, relates to a display substrate, a touch display panel and a touch display device.

### BACKGROUND

In modern electronic display device technology, connecting pins (usually called PIN pins) in a display substrate play an indispensable core role. The pins are responsible for establishing a precise bonding connection with a driving integrated circuit (a Driving IC, also known as a driving chip) and a flexible printed circuit (FPC), thus forming a key network for signal transmission.

However, in actual application environments, when a protective barrier of a display panel fails to effectively resist external damage, water molecules or conductive ions have the opportunity to penetrate into the interior of the display panel. Over time and under the influence of temperature, humidity, and electric fields, the water molecules and conductive ions will diffuse in the display panel. Once the water molecules and conductive ions interact with the connecting pins, the connecting pins will be corroded, and electrical short circuits or connection failure (i.e., open circuits) will happen between the connecting pins, thereby causing partial or complete functional damage to the display panel.

### SUMMARY

One aspect of the present disclosure provides a display substrate. The display substrate includes: a base substrate including a bonding area; and first connecting pins and second connecting pins in the bonding area. Along a direction from the first connecting pins to the second connecting pins, an insulating structure is provided between the first connecting pins and the second connecting pins. One first connecting pin and one second connecting pin adjacent to each other are disposed in different conductive layers.

Another aspect of the present disclosure provides a touch display panel. The touch display panel includes a display substrate. The display substrate includes: a base substrate including a bonding area; and first connecting pins and second connecting pins in the bonding area. Along a direction from the first connecting pins to the second connecting pins, an insulating structure is provided between the first connecting pins and the second connecting pins. One first connecting pin and one second connecting pin adjacent to each other are disposed in different conductive layers.

Another aspect of the present disclosure provides a touch display device. The touch display device includes a touch display panel. The touch display panel includes a display substrate. The display substrate includes: a base substrate including a bonding area; and first connecting pins and second connecting pins in the bonding area. Along a direction from the first connecting pins to the second connecting pins, an insulating structure is provided between the first connecting pins and the second connecting pins. One first connecting pin and one second connecting pin adjacent to each other are disposed in different conductive layers.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a display substrate;

FIG. 2 illustrates a top view of an exemplary display substrate consistent with various disclosed embodiments in the present disclosure;

FIG. 3 illustrates a cross-sectional view of an exemplary display substrate in FIG. 2 along an A1-A2 direction, consistent with various disclosed embodiments in the present disclosure;

FIG. 4 illustrates a cross-sectional view of another exemplary display substrate consistent with various disclosed embodiments in the present disclosure;

FIG. 5 illustrates a cross-sectional view of another exemplary display substrate consistent with various disclosed embodiments in the present disclosure;

FIG. 6 illustrates a top view of another exemplary display substrate consistent with various disclosed embodiments in the present disclosure;

FIG. 7 illustrates a cross-sectional view of another exemplary display substrate consistent with various disclosed embodiments in the present disclosure;

FIG. 8 illustrates a cross-sectional view of another exemplary display substrate consistent with various disclosed embodiments in the present disclosure;

FIG. 9 illustrates a cross-sectional view of another exemplary display substrate consistent with various disclosed embodiments in the present disclosure;

FIG. 10 illustrates a cross-sectional view of another exemplary display substrate consistent with various disclosed embodiments in the present disclosure;

FIG. 11 illustrates a partial top view of another exemplary display substrate consistent with various disclosed embodiments in the present disclosure;

FIG. 12 illustrates a cross-sectional view of another exemplary display substrate consistent with various disclosed embodiments in the present disclosure;

FIG. 13 illustrates a cross-sectional view of another exemplary display substrate consistent with various disclosed embodiments in the present disclosure;

FIG. 14 illustrates a cross-sectional view of another exemplary display substrate consistent with various disclosed embodiments in the present disclosure;

FIG. 15 illustrates a cross-sectional view of another exemplary display substrate consistent with various disclosed embodiments in the present disclosure;

FIG. 16 illustrates a cross-sectional view of another exemplary display substrate consistent with various disclosed embodiments in the present disclosure;

FIG. 17 illustrates a cross-sectional view of another exemplary display substrate consistent with various disclosed embodiments in the present disclosure;

FIG. 18 illustrates an exemplary touch display panel consistent with various disclosed embodiments in the present disclosure; and

FIG. 19 illustrates an exemplary touch display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or area is referred to as being “on” or “above” another layer or another area, the layer or area may be directly on another layer or area, or indirectly on another layer or area, for example, layers/components between the layer or area and another layer or another area. And, for example, when the component is reversed, the layer or area may be “below” or “under” another layer or area. In the present disclosure, the term “electrical connection” refers to that two components are directly electrically connected with each other, or the two components are electrically connected via one or more other components.

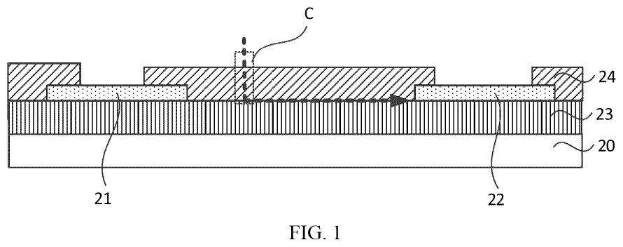

FIG. 1 shows a structure of a display substrate in existing technologies. As shown in FIG. 1, the display substrate includes: a base substrate 20, a first insulating layer 23 located on one side of the base substrate 20, and a first connecting pin 21 and a second connecting pin 22 located on the first insulating layer 23. The first connecting pin 21 and the second connecting pin 22 are made of the same conductive layer. A second insulating layer 24 is also provided on the conductive layer accommodating the first connecting pin 21 and the second connecting pin 22. The second insulating layer 24 exposes the first connecting pin 21 and the second connecting pin 22.

Since the first connecting pin 21 and the second connecting pin 22 are made of the same conductive layer, the distance between the first connecting pin 21 and the second connecting pin 22 is relatively small because of the space limitation of the display substrate. When entering the interior of the display panel from a damaged part C, water molecules or conductive ions will diffuse to the surroundings. The dotted arrows in FIG. 1 exemplarily illustrate a diffusion path of the water molecules or conductive ions. When the water molecules or conductive ions diffuse to the second connecting pin 22, they will corrode the second connecting pin 22 to cause an electrical short circuit or connection failure (i.e., open circuit) between the connecting pins, thereby resulting in partial or overall functional damage to the display panel.

The present disclosure provides a display substrate to at least partially alleviate the above problems. The display substrate provided by the present disclosure may include a base substrate. The base substrate may include a bonding area. First connecting pins and second connecting pins may be disposed in the bonding area. Along a direction from one first connecting pin to one adjacent second connecting pin, an insulating structure may be disposed between the first connecting pin and the adjacent second connecting pin. One first connecting pin and one adjacent second connecting pin may be disposed in different conductive layers.

A coordinate system is drawn in some of the drawings. The X-axis and the Y-axis in the coordinate system are parallel to a plane where the substrate is located, and the Z-axis in the coordinate system is perpendicular to the plane where the substrate is located.

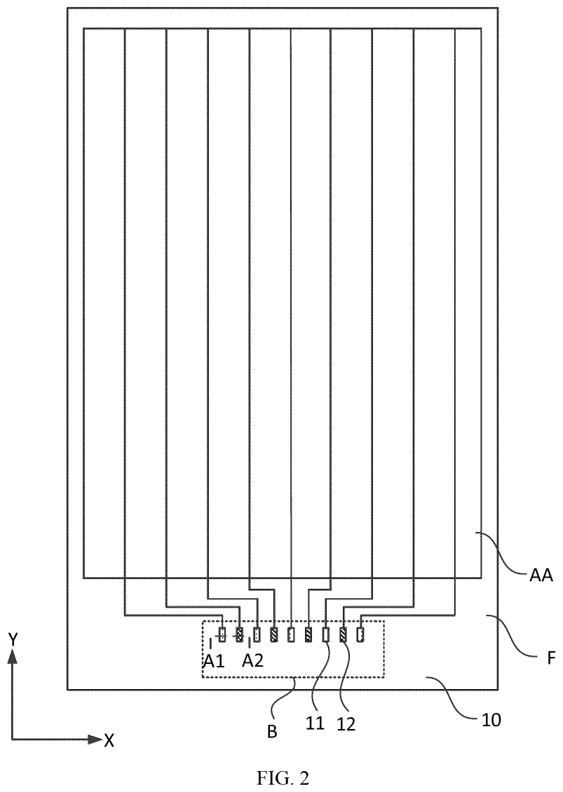

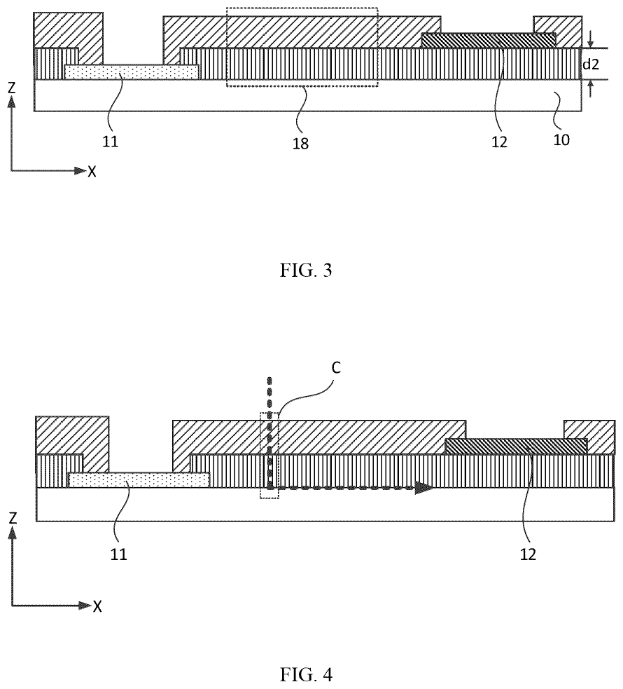

The present disclosure provides a display substrate. As shown in FIG. 2 which is a structure of an exemplary display substrate provided by the present disclosure and FIG. 3 which is a cross-sectional view of the display substrate in FIG. 2 along an A1-A2 direction, in one embodiment, the base substrate 10 may include a display area AA and a non-display area F surrounding the display area AA. The non-display area F may include a bonding area B. A plurality of first connecting pins 11 and a plurality of second connecting pins 12 may be disposed in the bonding area B. The plurality of first connecting pins 11 and a plurality of second connecting pins 12 may be arranged alternately along a direction from the plurality of first connecting pins 11 to the plurality of second connecting pins 12 (such as the X-axis direction in FIG. 2). An insulating structure 18 may be disposed between the plurality of first connecting pins 11 and the plurality of second connecting pins 12. One first connecting pin 11 of the plurality of first connecting pins 11 and one adjacent second connecting pin 12 of the plurality of second connecting pins 12 may be disposed in different conductive layers.

The base substrate may be a flexible substrate (such as a polyimide film), or a rigid substrate (such as a glass substrate).

The embodiment shown in FIG. 2 where the plurality of first connecting pins 11 and the plurality of second connecting pins 12 are disposed in the bonding area B is used as an example only to illustrate the present disclosure, and does not limit the scope of the present disclosure. In various embodiments, the number of the plurality of first connecting pins 11 may be one or more, or the number of the plurality of second connecting pins 12 may also be one or more.

The insulating structure 18 may be disposed between the plurality of first connecting pins 11 and the plurality of second connecting pins 12. That is, the plurality of first connecting pins 11 and the plurality of second connecting pins 12 may be insulated from each other.

The plurality of first connecting pins 11 and the plurality of second connecting pins 12 may be used for bonding with a flexible circuit board and/or a driving chip to transmit corresponding signals to electronic components (not shown) on the display substrate.

One first connection pin 11 of the plurality of first connection pins 11 and one adjacent second connection pin 12 of the plurality of second connection pins 12 may be disposed in different conductive layers. That is, the first connection pin 11 and the adjacent second connection pin 12 may be made of conductive layers formed by different process sequences, rather than made of conductive layers made by the same process sequence. Conductive materials in different conductive layers may be the same or different.

A distance between a surface of the first connection pin 11 close to the base substrate 10 and a surface of the base substrate 10 close to the first connection pin 11 may be a first distance, and a distance between a surface of the adjacent second connection pin 12 close to the base substrate 10 and a surface of the base substrate close to the adjacent second connection pin 12 may be a second distance. Exemplarily, the second distance d2 is shown in FIG. 3. Since the first connection pin 11 and the adjacent second connection pin 12 may be made of different conductive layers, the first distance and the second distance may be different. Exemplarily, in one embodiment shown in FIG. 3, the first distance may be smaller than the second distance.

In one embodiment, the base substrate 10 may be a glass substrate, and a buffer layer (not shown in FIG. 3) may be further disposed between the first connection pin 11 and the base substrate 10. The buffer layer may be an insulating layer. In some other embodiments, the buffer layer may not be included between the first connection pin 11 and the base substrate 10. At this time, as shown in FIG. 3, along the direction perpendicular to the plane where the base substrate 10 is located (i.e., the Z-axis direction in FIG. 3), the adjacent second connection pin 12 may be located on a side of the first connection pin 11 away from the base substrate 10. A distance from a lower surface of the first connection pin 11 to an upper surface of the glass substrate may be a first distance, and a distance from a lower surface of the adjacent second connection pin 12 to the upper surface of the glass substrate may be a second distance. The first distance may be smaller than the second distance.

In one embodiment, the base substrate 10 may be a polyimide film. A buffer layer (not shown in FIG. 3) may be further disposed between the first connection pin 11 and the base substrate 10. The buffer layer may be an insulating layer, and the insulating layer may be made of a material including silicon. In some other embodiments, the buffer layer may not be included between the first connection pin 11 and the base substrate 10. At this time, along the direction perpendicular to the plane where the base substrate is located (i.e., the Z-axis direction in FIG. 3), the distance from the lower surface of the first connection pin 11 to the upper surface of the polyimide film may be a first distance, and the distance from the lower surface of the second connection pin 12 to the upper surface of the polyimide film may be a second distance. The first distance may be smaller than the second distance.

The dotted arrows in FIG. 4 exemplarily illustrate a propagation path of the water molecules or conductive ions. Since the insulating layer is usually an inorganic layer, the water molecules or conductive ions may not be able to break through the inorganic layer for cross-layer diffusion when the insulating layer is not damaged, and may diffuse in the layer. As shown in FIG. 4, in some cases, because of external force or process influence, the insulating layer may be damaged at a position of C, and the water molecules or conductive ions may penetrate into the display substrate from the damaged part C and diffuse to the surroundings. Since the first connecting pin 11 and the adjacent second connecting pin 12 are located in different conductive layers, when the water molecules or conductive ions diffuse along the path indicated by the dotted arrows in FIG. 4, the path for the water molecules or conductive ions to diffuse to the adjacent second connecting pin 12 may become longer. That is, the time for the water molecules or conductive ions to reach the adjacent second connecting pin 12 may be longer, and the corrosion of the adjacent second connecting pin 12 may be delayed.

Therefore, the diffusion path of the water molecules and conductive ions may be extended by disposing the first connecting pin 11 and the adjacent second connecting pin 12 in different conductive layers, delaying the corrosion of the first connecting pin 11 and/or the adjacent second connecting pin 12 and extending the life of the display substrate.

Materials for forming the plurality of first connecting pins 11 and the plurality of second connecting pins 12 are not limited in the present disclosure, as long as they can be electrically connected to the flexible circuit board and/or the driving chip. For example, in one embodiment, the plurality of first connecting pins may be made of a material including indium tin oxide or a metal, and the plurality of second connecting pins be made of a material including indium tin oxide or metal.

In one embodiment, since indium tin oxide is a transparent material which is conducive to light transmission while metal is not conducive to light transmission, to ensure that a display panel including the display substrate has a better display effect, fingerprint recognition effect and touch effect, one conductive layer relatively close to the base substrate may be set to be metal, and another conductive layer relatively far from the base substrate may be set to be indium tin oxide. The conductive layer relatively close to the base substrate and the conductive layer relatively far from the base substrate may be used to from electrodes or wirings for realizing image display function, fingerprint recognition function or touch function. In the first connecting pin and the adjacent second connecting pin, the material of one connecting pin relatively close to the base substrate may include metal, and the material of another connecting pin relatively far from the base substrate may include indium tin oxide. Therefore, the first connecting pin and the adjacent second connecting pin and other conductive structures (such as electrodes or traces) in the display substrate may be formed in one same step, and there may be no need to form a conductive layer specifically for forming the first connecting pin and the adjacent second connecting pins. The manufacturing cost of the display substrate may be reduced and the manufacturing effect of the display substrate may be improved.

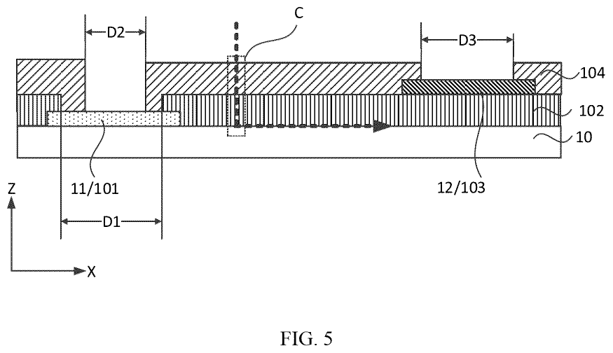

In some embodiments as shown in FIG. 5, the display substrate may further include a first conductive layer 101 on a side of the base substrate 10. The plurality of first connecting pins 11 may be disposed in the first conductive layer 101 in the bonding area. The display substrate may also include a first insulating layer 102 on the first conductive layer 101. The first insulating layer 102 may include a plurality of first hollow areas D1. One first hollow area D1 of the plurality of first hollow areas D1 may expose at least a portion of one corresponding first connecting pin of the plurality of first connecting pins 11. The display substrate may also include a second conductive layer 103 located on the first insulating layer 102. The plurality of second connecting pins 12 may be disposed in the second conductive layer 103. Along the direction from the plurality of first connecting pins 11 to the plurality of second connecting pins 12 (i.e., the X-axis direction in FIG. 5), the plurality of first connecting pins 11 and the plurality of second connecting pins 12 may be alternately arranged. The display substrate may also include a second insulating layer 104 located on the second conductive layer 103. The second insulating layer 104 may include second hollow areas D2 and third hollow areas D3. One second hollow area D2 may expose at least a portion of one corresponding first hollow area D1; and one third hollow area D3 may expose at least a portion of one corresponding second connecting pin 12 of the plurality of second connecting pins 12. The purpose of such arrangement is to provide a display substrate arrangement scheme that meets the requirement that one first connecting pin 11 and one adjacent second connecting pins 12 are located in different conductive layers, to extend the diffusion path of the water molecules and conductive ions, delay the corrosion of the first connecting pin 11 and/or the second connecting pin 12, and thereby extend the life of the display substrate.

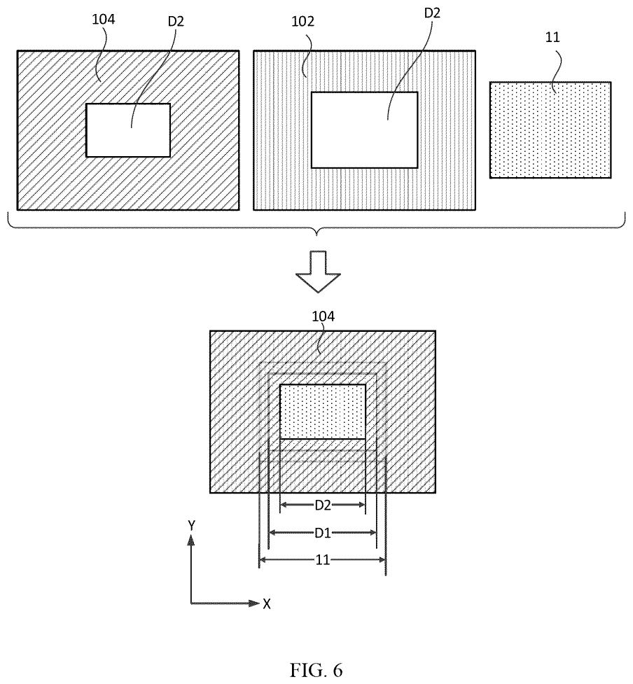

In FIG. 6, the portion above the arrow shows a schematic diagram of the second insulating layer 104, the first insulating layer 102 and one first connecting pin 11; and the portion below the arrow shows a schematic diagram after the second insulating layer 104, the first insulating layer 102 and the first connecting pin 11 are overlapped. Each film layer in FIG. 6 is a top view. As shown in FIG. 5 and FIG. 6, a projection of one first hollow area D1 on the base substrate 10 may be a first projection; a projection of one corresponding second hollow area D2 on the base substrate 10 may be a second projection, and a projection of one corresponding first connecting pin 11 on the base substrate 10 may be a third projection. The second projection may be within the first projection, and the first projection may be within the third projection. Therefore, the first connecting pin 11 may be exposed, ensuring that the first connecting pin 11 is effectively bonded to the flexible circuit board and/or the driving chip. Also, the second insulating layer 104 may fully cover the first insulating layer 102. Therefore, when the first insulating layer 102 is damaged, the second insulating layer 104 may block water molecules or conductive ions from penetrating from the damaged part of the first insulating layer 102 under the barrier effect if the second insulating layer 104 covering the first insulating layer 102 is not damaged.

In some embodiments shown in FIG. 7, the display substrate may also include grooves 105 that penetrate the first insulating layer 102 and the second insulating layer 104. One groove 105 may be located between one first connecting pin 11 and one adjacent second connecting pin 12, in the direction from the first connecting pin 11 to the adjacent second connecting pin 12 (i.e., the X-axis direction in FIG. 7). The groove 105 may be used to accommodate a barrier structure later, to achieve the purpose of using the barrier structure to block the water molecules or conductive ions from continuing to diffuse along the X-axis direction in the figure during actual use.

It should be noted that the step of forming a barrier structure in the groove 105 may be performed during the production of the display substrate, or may be performed during the process of bonding the manufactured display substrate with the flexible circuit board and/or the driving chip, which is not limited in the present disclosure. That is, the manufactured display substrate includes the grooves 105, and one groove 105 may have a barrier structure or may not have a barrier structure. When there is no barrier structure in the groove 105, a barrier structure filling the groove 105 may be formed during the process of bonding the display substrate with the flexible circuit board and/or the driving chip.

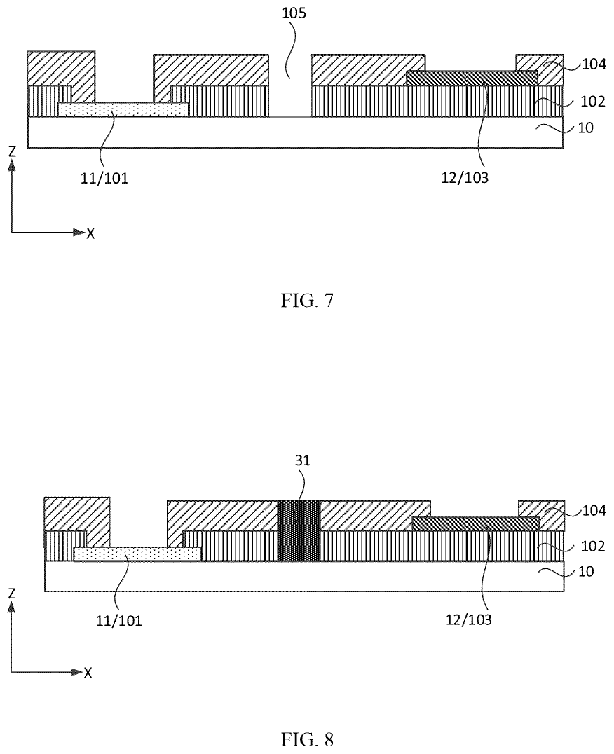

In one embodiment shown in FIG. 8, in the manufactured display substrate, each groove 105 may be filled with a barrier structure 31, to utilize the barrier structure 31 to block the water molecules or conductive ions from continuing to diffuse along the X-axis direction in the figure. Furthermore, the barrier structure 31 may be made of an inorganic material. Compared with organic materials, an inorganic material may have better barrier capabilities for water molecules or conductive ions, and may be able to form a barrier to cut off the diffusion path of water molecules or conductive ions, thereby achieving the purpose of delaying the corrosion of the plurality of first connecting pins 11 and/or the plurality of second connecting pins 12 and extending the life of the display substrate.

In another embodiment, in the manufactured display substrate, each groove may be not filled with a barrier structure, and the barrier structure may be made of a conductive adhesive that overflows into the groove during the bonding process of the display substrate with other electronic devices. In this case, optionally, the barrier structure may be made of a material including anisotropic conductive adhesive.

In one embodiment, the method of bonding the display substrate with other electronic devices may include: applying anisotropic conductive adhesive to the display substrate and/or the electronic devices; applying pressure to the electronic devices and the display substrate to make the anisotropic conductive adhesive overflow into the grooves; and curing the anisotropic conductive adhesive such that the anisotropic conductive adhesive overflows into the grooves and forms barrier structures.

The anisotropic conductive adhesive is a special type of adhesive that is liquid in the initial state and is able to flow and change position under the action of external pressure. Once cured or dried, the anisotropic conductive adhesive will have stable conductive properties.

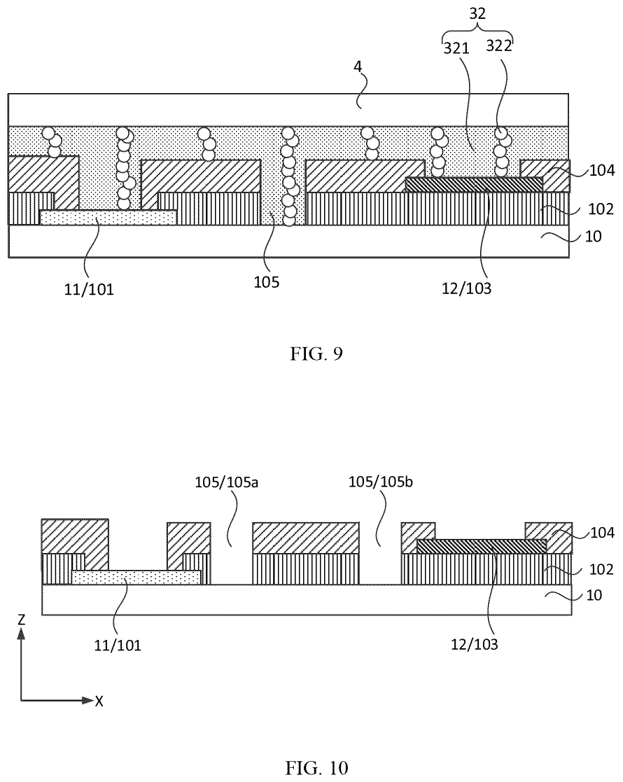

FIG. 9 illustrates a schematic diagram of bonding the display substrate in FIG. 7 with other electronic devices. In one embodiment shown in FIG. 9, the display substrate may be bonded to another electronic device 4 through the anisotropic conductive adhesive 32. The electronic device 4 may include the flexible circuit boards and/or driving chip. The anisotropic conductive adhesive 32 may include a base resin 321 and conductive particles 322. During the manufacturing process, the base resin 321, by virtue of its bonding properties, may effectively combine the conductive particles 322 tightly into one body to construct a continuous conductive path. Therefore, the anisotropic conductive adhesive is able to achieve a stable and well-conductive connection between the display substrate and/or the electronic device 4, and may achieve the purpose of reusing the anisotropic conductive adhesive overflowing into the grooves as the barrier structures.

In various embodiments, along the direction from the first connecting pin to the adjacent second connecting pin, the number of grooves disposed between the first connecting pin to the adjacent second connecting pin may be one or more, which is not limited in the present disclosure.

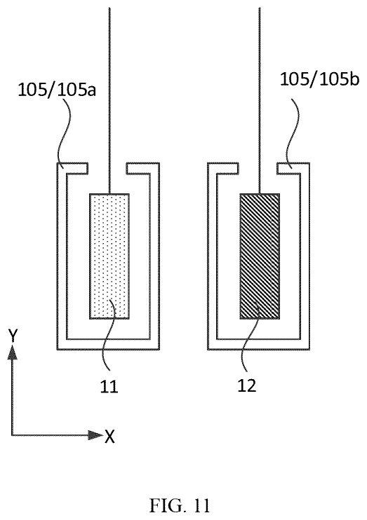

In one embodiment shown in FIG. 10 which is a cross-sectional view of a display substrate and FIG. 11 which is a top view of the display substrate, along the direction from the first connecting pin 11 to the adjacent second connecting pin 12, at least two grooves 105 may be disposed between the first connecting pin 11 to the adjacent second connecting pin 12 (the embodiment shown in FIG. 10 where two grooves are shown is used as an example only to illustrate the present disclosure). The at least two grooves 105 may include a first groove 105a and a second groove 105b. The first groove 105a may surround the first connecting pin 11 and the second groove 105b may surround the adjacent second connecting pin 12.

In practice, water molecules and conductive ions may diffuse in all directions between layers. By setting the first groove 105a to surround the first connecting pin 11, the barrier structure subsequently filled into the first groove 105a may surround the first connecting pin 11 as much as possible, and block the diffusion of water molecules and conductive ions from as many directions as possible, to prevent the water molecules and conductive ions from diffusing to the first connecting pin 11 and corroding the first connecting pin 11. By setting the second groove 105b to surround the adjacent second connecting pin 12, the barrier structure subsequently filled into the second groove 105b may surround the second connecting pin 12 as much as possible, and block the diffusion of water molecules and conductive ions from as many directions as possible, to prevent the water molecules and conductive ions from diffusing to the second connecting pin 12 and corroding the second connecting pin 12.

In some embodiments, in the bonding area, along the direction from the first connecting pin to the adjacent second connecting pin, a floating pin may be disposed between the first connecting pin and the adjacent second connecting pin. Along the direction from the first connecting pin to the floating pin, an insulating structure may be disposed between the first connecting pin and the floating pin. Along the direction from the second connecting pin to the floating pin, an insulating structure may be disposed between the second connecting pin and the floating pin.

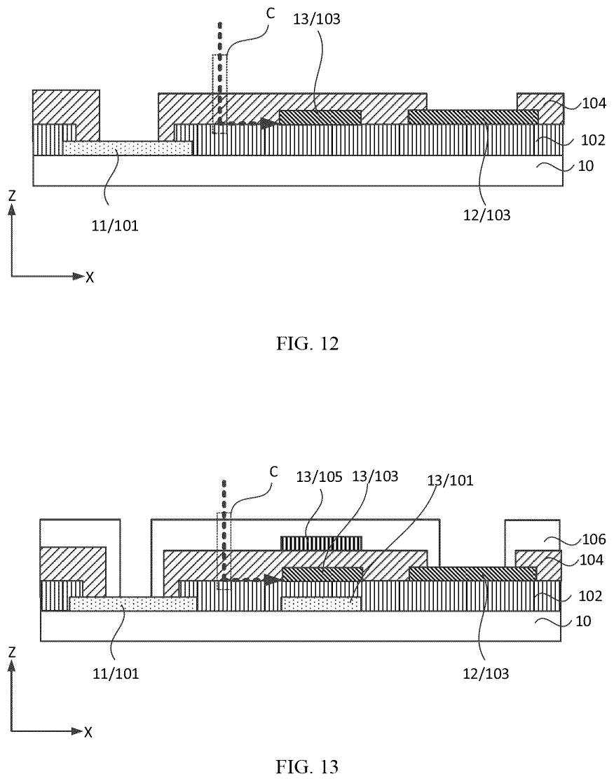

In one embodiment shown in FIG. 12, along the direction from the first connecting pin 11 to the adjacent second connecting pin 12, a floating pin 13 may be disposed between the first connecting pin 11 and the adjacent second connecting pin 12. The first connecting pin 11 and the floating pin 13 may be insulated from each other. The adjacent second connecting pin 12 and the floating pin 13 may be insulated from each other. The floating pin 13 and the adjacent second connecting pin 12 may be located in a same conductive layer.

As shown in FIG. 12, assuming that the insulating structure between the first connecting pin 11 and the floating pin 13 is damaged, after water molecules or conductive ions penetrate from the damaged part C, some water molecules or conductive ions may diffuse along the direction from the first connecting pin 11 to the adjacent second connecting pin 12 (i.e., the X-axis direction in FIG. 12). Because of the floating pin 13, some water molecules or conductive ions may first corrode the floating pin 13. After the floating pin 13 is corroded thoroughly, the water molecules or conductive ions may continue to diffuse along the direction from the first connecting pin 11 to the adjacent second connecting pin 12. That is, the floating pin 13 may act as a sacrificial layer, which slows down the diffusion progress of water molecules or conductive ions to the second connecting pin 12 by sacrificing itself. Therefore, the time for water molecules or conductive ions to reach the second connecting pin 12 may become longer, thereby achieving the purpose of delaying the corrosion of the second connecting pin 12.

In FIG. 12, the floating pin 13 may be disposed in the second conductive layer 103. The embodiment shown in FIG. 12 is used as an example only to illustrate the present disclosure, and does not limit the scope of the present disclosure. In some other embodiments, the floating pin may be disposed at least one of the following positions: the first conductive layer, the second conductive layer, or the third conductive layer. The third conductive layer may be located at a side of the second insulating layer away from the base substrate.

In another embodiment shown in FIG. 13, the display substrate may further include a third conductive layer 106 and a third insulating layer 106. The third conductive layer 106 may be located on the second insulating layer 104. Floating pins 13 may be disposed in the third conductive layer 106, and the third conductive layer 106 may expose at least a portion of each first connecting pin 11 and at least a portion of each second connecting pin 12. The third insulating layer 106 may be located on the third conductive layer 106. The third insulating layer 106 may cover the floating pins 13, and the third insulating layer 106 may expose at least a portion of each first connecting pin 11 and at least a portion of each second connecting pin 12. In one embodiment shown in FIG. 13, three floating pins 13 may be provided between one first connecting pin 11 and one adjacent second connecting pin 12, and the three floating pins 13 may be respectively disposed in the first conductive layer 101, the second conductive layer 102, and the third conductive layer 106. Regardless of which conductive layer the suspension pins 13 are provided in, the floating pins 13 may slow down the diffusion of water molecules or conductive ions between the upper and lower layers in contact with the floating pins 13.

In the embodiment shown in FIG. 12, one floating pin 13 may be provided between one first connecting pin 11 and one adjacent second connecting pin 12. In the embodiment shown in FIG. 13, three floating pins 13 may be provided between one first connecting pin 11 and one adjacent second connecting pin 12. The embodiments shown in FIG. 12 and FIG. 13 are used as examples only to illustrate the present disclosure, and do not limit the scope of the present disclosure. In various embodiments, N floating pins 13 may be provided between one first connecting pin 11 and one adjacent second connecting pin 12, where N may be an integer larger than or equal to 1. Also, numbers of floating pins 13 in different layers may be different.

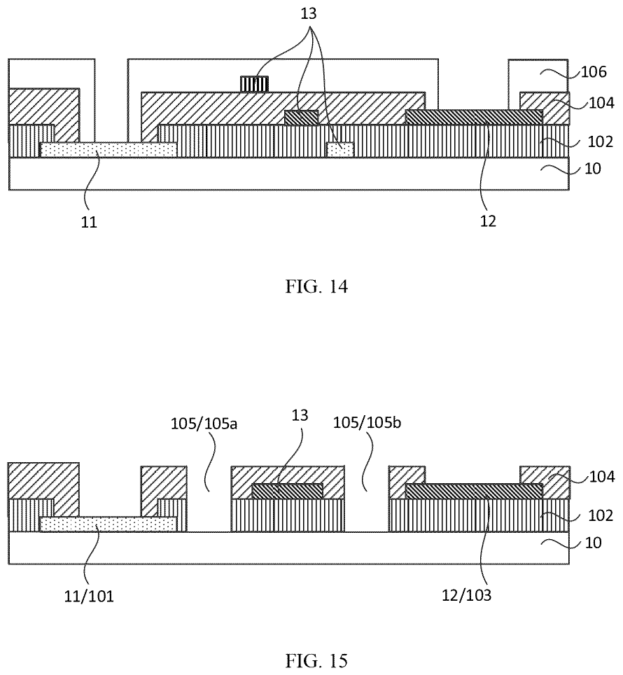

In the embodiment shown in FIG. 13, along the direction perpendicular to the base substrate 10 (along the Z-axis in FIG. 13), the three floating pins may overlap. The embodiments shown in FIG. 12 and FIG. 13 are used as examples only to illustrate the present disclosure, and do not limit the scope of the present disclosure. In various embodiments, along the direction perpendicular to the base substrate 10, the floating pins may or may not overlap. For example, in one embodiment shown in FIG. 14, any two floating pins in different layers may not overlap along the direction perpendicular to the base substrate 10.

In one embodiment, the voltage on one floating pin may be set to 0. That is, voltage may not be applied to the floating pin, and no signal line may be set for the floating pin.

In some embodiments, the display substrate may also include a plurality of grooves penetrating the first insulating layer and the second insulating layer. The plurality of grooves may be located between adjacent first connecting pins and second connecting pins along the direction from the first connecting pins to the second connecting pins. The floating pins and the grooves may be alternately arranged along the direction from the first connecting pins to the second connecting pins.

In one embodiment shown in FIG. 15, along the direction from the first connecting pin 11 to the adjacent second connecting pin 12, two grooves 105 and one floating pin 13 may be disposed between the first connecting pin 11 and the adjacent second connecting pin 12. Along the direction from the first connecting pin 11 to the adjacent second connecting pin 12, the first groove 105a, the floating pin 13, and the second groove 105b may be arranged sequentially.

The groove and the floating pin have different principles for delaying the diffusion of water molecules and conductive ions. The barrier structure in the groove may act as a physical barrier to hinder the diffusion of water molecules and/or conductive ions between layers, increasing the tortuosity of the diffusion path and reducing the invasion speed. The floating pin may act as a sacrificial layer, and sacrifice itself to delay the diffusion of water molecules and/or conductive ions to the first connecting pin and/or the second connecting pin. Along the direction from the first connecting pin to the adjacent second connecting pin, the floating pins and the grooves may be alternately arranged. Therefore, the physical barrier and the sacrificial layer may be combined, such that the two protection methods may complement each other, to improve the moisture and corrosion resistance of the display substrate, and thus increase the life of the display substrate.

In one embodiment, the first connecting pin may be made of a material including metal, and the adjacent second connecting pin may be made of a material including indium tin oxide. An auxiliary pin may be disposed between the adjacent second connecting pin and the base substrate in a direction perpendicular to the base substrate. The auxiliary pin may be electrically connected to the adjacent second connecting pin. A square resistance of the auxiliary pin may be lower than a square resistance of the adjacent second connecting pin.

When the block resistance of one connecting pin is smaller, the delay of the signal that needs to be transmitted through the connecting pin after the display substrate is bonded to the flexible circuit board and/or the driving chip may be smaller. Since the block resistance of indium tin oxide is often large, when the material of the second connecting pin is indium tin oxide, by setting the second connecting pin to be connected to the auxiliary pin with a smaller block resistance, the block resistance of the second connecting pin may be reduced, thereby reducing the delay of the signal transmitted through the second connecting pin.

Optionally, the material of the first connecting pin may be metal, and the material of the second connecting pin may also be metal. The first connecting pin may be disposed in a same layer and made of a same material as one of the signal lines in the pixel circuits in the display area, and the second connecting pin may also be disposed in a same layer and made of a same material as another signal line in the pixel circuits in the display area. It can be understood that the two signal lines may be located in different film layers and may be formed by different processes. The materials of the two signal lines may be the same or different.

In various embodiments, the auxiliary pin may be disposed in different positions and the present disclosure has no limit on this. For example, in one embodiment, the auxiliary pin may be disposed on a side of the second connecting pin close to the base substrate, that is, between the second connecting pin and the first insulating layer.

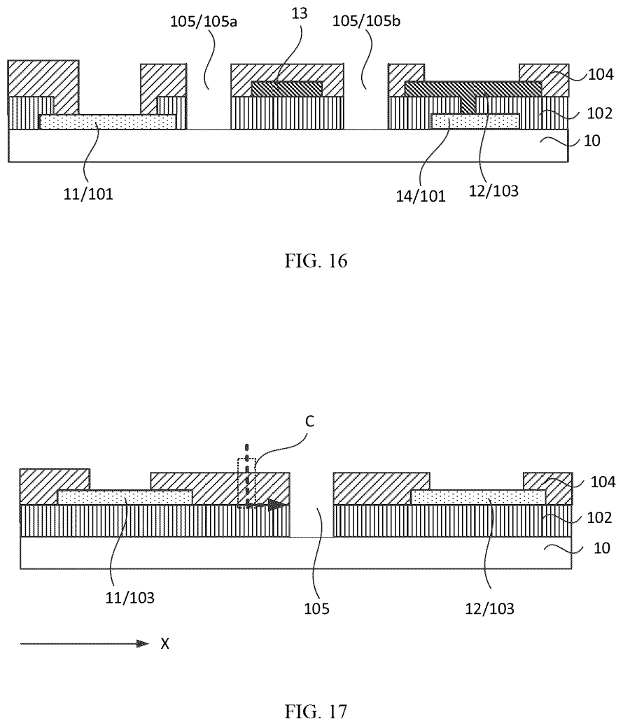

In one embodiment shown in FIG. 16, the auxiliary pin 14 may be located in the first conductive layer 101. The auxiliary pin 14 may be electrically connected to the second connecting pin 12 through a via hole penetrating the first insulating layer 102. Therefore, the auxiliary pin 14 and the first connecting pin 11 may be located in the same film layer and may be manufactured in the same process, reducing the manufacturing process of the display substrate and reducing the manufacturing cost of the display substrate.

In some embodiments, the first connection pin may be connected to a power line, a clock signal line, a data line, an idle line or a touch line. The second connection pin may be connected to a power line, a clock signal line, a data line, an idle line or a touch line. The idle line may be, for example, a dummy line in a display panel. The dummy line may be a connection wire that is deliberately added in the display area and is not used for various functions such as actual display of images, touch, fingerprint recognition, etc.

There may or may not be a voltage difference between the first connection pin and the adjacent second connection pin. Regardless of whether there is a voltage difference between the first connection pin and the adjacent second connection pin there may be diffusion of water molecules and conductive ions. For the case where there is a voltage difference between the first connection pin and the adjacent second connection pin, the technical solution provided by the present disclosure may suppress the diffusion of water molecules and/or conductive ions.

In some embodiments, the three implementations including setting the first connection pin and the adjacent second connection pin in different conductive layers, setting grooves between the first connection pin and the adjacent second connection pin, or setting floating pins between the first connection pin and the adjacent second connection pin to achieve protection through self sacrificing, may be adopted in combination or may be adopted independently. Any two or all three of the three implementations may be adopted. Or only one of the three implementations may be adopted.

In one embodiment, regardless whether the first connection pin and the adjacent second connection pin are disposed in different conductive layers or the floating pins are set between the first connection pin and the adjacent second connection pin, the grooves are set between the first connection pin and the adjacent second connection pin. The display substrate may include: a base substrate including a bonding area. First connection pins and second connecting pins may be disposed in the bonding area. An insulating structure may be disposed between one first connecting pin and one adjacent second connecting pin in a direction pointing from the first connecting pin to the adjacent second connecting pin. A groove may be provided in the insulating structure and penetrate through the insulating structure. The first connecting pin and the adjacent second connecting pin may be located in the same conductive layer.

In one embodiment shown in FIG. 17, for example, the first connecting pin 11 and the adjacent second connecting pin 12 may be located in the same conductive layer, and the insulating structure including a first insulating layer 102 and a second insulating layer 104 may be disposed between the first connecting pin 11 and the adjacent second connecting pin 12. One groove 105 may penetrate through the insulating structure between the first connecting pin 11 and the adjacent second connecting pin 12. The groove 105 may be used to accommodate a barrier structure later, to achieve the purpose of using the barrier structure to block water molecules or conductive ions from continuing to diffuse along the X-axis direction in the figure during actual use.

Similarly, the groove may be filled with a barrier structure. The barrier structure may be made of an inorganic material.

Further, the barrier structure may be formed by the inorganic material filled in the groove during the production of the display substrate; or, the barrier structure may be conductive adhesive overflowing into the groove during the process of bonding the display substrate with other electronic devices.

Further, along the direction from the first connecting pin to the adjacent second connecting pin, at least two grooves may be disposed between the first connecting pin and the adjacent second connecting pin. The at least two grooves may include a first groove and a second groove. The first groove may surround the first connecting pin, and the second groove may surround the adjacent second connecting pin.

Optionally, in the display panel, regardless whether the first connection pin and the adjacent second connection pin are disposed in different conductive layers or the grooves are set between the first connection pin and the adjacent second connection pin, floating pins may be set between the first connection pin and the adjacent second connection pin.

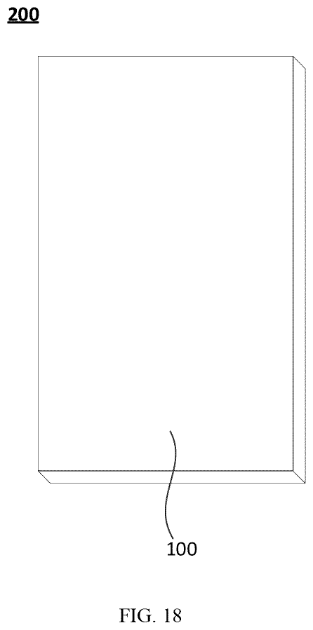

The present disclosure also provides a touch display panel. As shown in FIG. 18, in one embodiment, the touch display panel 200 may include any display substrate provided by various embodiments of the present disclosure. The touch display panel may be an organic light-emitting diode (OLED) display panel, a liquid crystal display (LCD) panel, or a micro light-emitting diode (micro-LED) display panel. The touch display panel provided by the present disclosure may have similar advantages as the display substrate provided by various embodiments of the present disclosure.

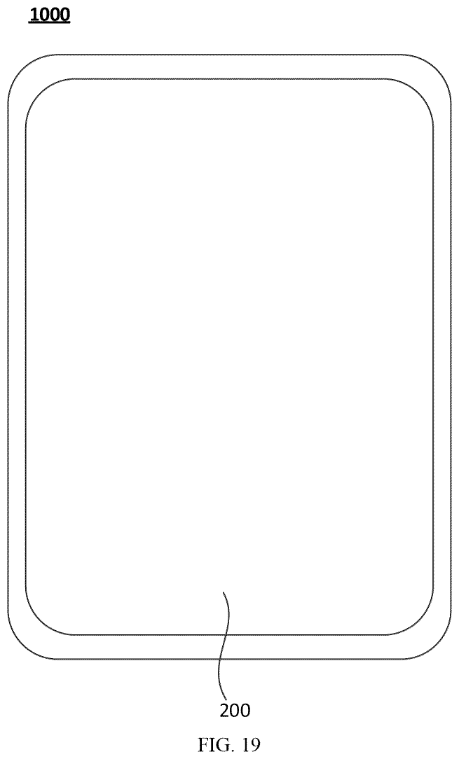

The present disclosure also provides a touch display device. In one embodiment shown in FIG. 19, the touch display device 1000 may include a touch display panel 200 provided by various embodiments of the present disclosure. The embodiment in FIG. 19 where the display device 1000 is a mobile phone is used as an example only to illustrate the present disclosure, and does not limit the scope of the present disclosure. The display device 1000 provided by the various embodiments of the present disclosure may be a wearable product, a computer, a television, a vehicle-loaded display device, or other devices with display functions. The type of the display device is not specifically limited in the present disclosure. The touch display device provided by the present disclosure may have similar advantages as the touch display panel provided by various embodiments of the present disclosure.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display substrate, comprising:
a base substrate including a bonding area; and
first connecting pins and second connecting pins in the bonding area,
wherein:
along a direction from the first connecting pins to the second connecting pins, an insulating structure is provided between the first connecting pins and the second connecting pins; and
one first connecting pin and one second connecting pin adjacent to each other are disposed in different conductive layers.

2. The display substrate according to claim 1, further including:
a first conductive layer located on one side of the base substrate, wherein the first connecting pins are located in the first conductive layer in the bonding area;
a first insulating layer located on the first conductive layer, wherein the first insulating layer includes a plurality of first hollow areas and each of the plurality of first hollow area exposes at least a portion of one corresponding first connecting pin;
a second conductive layer located on the first insulating layer, wherein: the second connecting pins are located in the second conductive layer, and the first connecting pins and the second connecting pins are alternately arranged along the direction from the first connecting pins to the second connecting pins; and
a second insulating layer located on the second conductive layer, wherein:
the second insulating layer includes second hollow areas and third hollow areas;
each second hollow area exposes at least a portion of one corresponding first hollow area and each third hollow area exposes at least a portion of one corresponding second connecting pin.

3. The display substrate according to claim 2, wherein:
a projection of one first hollow area on the base substrate is a first projection;
a projection of one corresponding second hollow area on the base substrate is a second projection;
a projection of one corresponding first connecting pin on the base substrate is a third projection; and
the second projection is within the first projection, and the first projection is within the third projection.

4. The display substrate according to claim 2, further including grooves penetrating through the first insulating layer and the second insulating layer, wherein:
the grooves are located between adjacent first connecting pins and second connecting pins in the direction from the first connecting pins to the second connecting pins.

5. The display substrate according to claim 4, wherein:
along the direction from the first connecting pins to the second connecting pins, at least two grooves are arranged between one first connecting pin and one second connecting pin adjacent to each other;
the at least two grooves include a first groove and a second groove; and
the first groove surrounds the first connecting pin, and the second groove surrounds the second connecting pin.

6. The display substrate according to claim 4, wherein:
each groove is filled with a barrier structure.

7. The display substrate according to claim 6, wherein:
the barrier structure is made of an inorganic material.

8. The display substrate according to claim 7, wherein:
the barrier structure is formed by an inorganic material filled in the groove during a manufacturing process of the display substrate; or
the barrier structure is formed by a conductive adhesive overflowing into the groove during a process of bonding the display substrate with other electronic devices.

9. The display substrate according to claim 8, wherein:
the barrier structure is formed by the conductive adhesive overflowing into the groove during the process of bonding the display substrate with the other electronic devices, and the barrier structure is made of an anisotropic conductive adhesive.

10. The display substrate according to claim 2, further including:
floating pins between one first connecting pin and one second connecting pin adjacent to each other in the bonding area along the direction from the first connecting pins to the second connecting pins,
wherein:
an insulating structure is provided between one first connecting pin and one corresponding floating pin in a direction from the first connecting pin to the corresponding floating pin; and
an insulating structure is provided between one second connecting pin and one corresponding floating pin in a direction from the second connecting pin to the corresponding floating pin.

11. The display substrate according to claim 10, wherein:
the floating pins are located in at least one of the first conductive layer, the second conductive layer, or a third conductive layer, wherein the third conductive layer is located on a side of the second insulating layer away from the base substrate.

12. The display substrate according to claim 10, further including grooves penetrating through the first insulating layer and the second insulating layer, wherein:
the grooves are located between adjacent first connecting pins and second connecting pins in the direction from the first connecting pins to the second connecting pins; and
in the direction from the first connecting pins to the second connecting pins, the grooves and the floating pins are arranged alternately.

13. The display substrate according to claim 2, wherein:
the first connecting pins are made of a material including indium tin oxide or metal; and
the second connecting pins are made of a material including indium tin oxide or metal.

14. The display substrate according to claim 13, wherein:
the first connecting pins are made of a material including metal; and the second connecting pins are made of a material including indium tin oxide;
in a direction perpendicular to the base substrate, an auxiliary pin is provided between one second connecting pin and the base substrate;
the auxiliary pin is electrically connected to the second connecting pin; and
a square resistance of the auxiliary pin is lower than a square resistance of the second connecting pin.

15. The display substrate according to claim 14, wherein:
the auxiliary pin is located in the first conductive layer; and the auxiliary pin is electrically connected to the second connecting pin through a via hole penetrating the first insulating layer.

16. The display substrate according to claim 1, wherein:
the first connection pins are connected to a power line, a clock signal line, a data line, an idle line or a touch line; and
the second connection pins are connected to a power line, a clock signal line, a data line, an idle line or a touch line.

17. The display substrate according to claim 1, wherein:
the first connecting pins and the second connecting pins are used to bond to a flexible circuit board and/or a driving chip.

18. A touch display panel, comprising a display substrate, wherein
the display substrate includes:
a base substrate including a bonding area; and
first connecting pins and second connecting pins in the bonding area,
wherein:
along a direction from the first connecting pins to the second connecting pins, an insulating structure is provided between the first connecting pins and the second connecting pins; and
one first connecting pin and one second connecting pin adjacent to each other are disposed in different conductive layers.

19. A touch display device comprising a touch display panel, wherein:
the touch display panel includes a display substrate; and
the display substrate includes:
a base substrate including a bonding area; and
first connecting pins and second connecting pins in the bonding area,
wherein:
along a direction from the first connecting pins to the second connecting pins, an insulating structure is provided between the first connecting pins and the second connecting pins; and
one first connecting pin and one second connecting pin adjacent to each other are disposed in different conductive layers.
